(19) United States
(12) Patent Application Publication
(10) Pub. No.: US 2025/0293113 A1
(43) Pub. Date: Sep. 18, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Cheng-Lun CHEN, Taichung City (TW); Liang-Yi HUNG, Taichung City (TW); Yu-Po WANG, Taichung City (TW)

(73) Assignee: SILICONWARE PRECISION INDUSTRIES CO., LTD., Taichung City (TW)

(21) Appl. No.: 18/899,845

(22) Filed: Sep. 27, 2024

(30) Foreign Application Priority Data
Mar. 12, 2024 (TW) 113109040

(51) Int. Cl. H01L 23/367; H01L 21/48; H01L 23/10; H01L 23/31; H01L 23/373; H01L 23/498

(52) U.S. Cl. CPC H01L 23/3675; H01L 21/481; H01L 21/4882; H01L 23/10; H01L 23/3736; H01L 23/49833; H01L 23/3107

(57) ABSTRACT

An electronic package is provided, including a carrier structure; a packaging module disposed on one side of the carrier structure and including an encapsulation layer, an electronic component, a circuit structure, and a wiring structure, wherein the encapsulation layer has a first surface and a second surface opposing the first surface, the electronic component is embedded in the encapsulation layer, the circuit structure is formed on the second surface of the encapsulation layer and electronically connected to the electronic component, and the wiring structure is formed on the first surface of the encapsulation layer and electronically connected to the electronic component; and a heat dissipation structure formed on the circuit structure of the packaging module. A manufacturing method of an electronic package is further provided.

### BACKGROUND

### 1. Technical Field

The present disclosure relates to an electronic package and a manufacturing method thereof, and more particularly, to an electronic package with heat dissipation structure and a manufacturing method thereof.

### 2. Description of Related Art

With the vigorous development of the electronics industry, electronic products are gradually moving towards multi-function and high performance. Therefore, the industry has carried out innovative development of chips and developed the technology of Backside Power Delivery Network (BSPDN) chips. The difference between it and traditional chips is that the signal (I/O signal), power and ground lines of the elements inside the traditional chip are transmitted outward in the same direction, while the backside power delivery chip can transfer the power and ground contacts from the backside of the chip which is exported in the opposite direction to the signal lines. The advantage is that the signal line side not only reduces interference from the power lines, but also frees up space for design routing.

FIG. 1 is a schematic cross-sectional view of a conventional semiconductor package 1. As shown in FIG. 1, the semiconductor package 1 in which a semiconductor chip 11 and a plurality of conductive pillars 13 are embedded in an encapsulating layer 15, and a circuit structure 16 is formed on an upper side of the encapsulating layer 15 and electrically connected to the plurality of conductive pillars 13, and a wiring structure 10 is formed on a lower side of the encapsulating layer 15 and electrically connected to the plurality of conductive pillars 13, wherein the semiconductor chip 11 is a backside power delivery chip having a power line side 11a and a signal line side 11b opposing the power line side 11a. The power line side 11a is electrically connected to the wiring structure 10, and the signal line side 11b is electrically connected to the circuit structure 16. The wiring structure 10 is disposed on a substrate 12 through a plurality of conductive bumps 14 and an underfill 17, and the substrate 12 may be connected to a circuit board (not shown) through a plurality of solder balls 18.

In the conventional semiconductor package 1, the semiconductor chip 11 may only dissipate heat by conducting heat to the plurality of conductive bumps 14 and the substrate 12 through the wiring structure 10 on the power line side 11a. There is no heat dissipation structure on the signal line side 11b, resulting in a risk of overheating the semiconductor package 1 due to heat accumulation.

Therefore, there is a need for a solution that addresses the aforementioned shortcomings in the prior art.

### SUMMARY

In view of the aforementioned shortcomings of the prior art, the present disclosure provides an electronic package, which comprises: a carrier structure; and a packaging module disposed on one side of the carrier structure and including an encapsulating layer, an electronic component, a circuit structure, and a wiring structure, wherein the encapsulating layer has a first surface and a second surface opposing the first surface, the electronic component is embedded in the encapsulating layer, the circuit structure is formed on the second surface of the encapsulating layer and electrically connected to the electronic component, and the wiring structure is formed on the first surface of the encapsulating layer and electrically connected to the electronic component, and the electronic component is a backside power delivery chip having a power line side and a signal line side opposing the power line side, wherein one of the power line side and the signal line side is electrically connected to the wiring structure, and another one of the signal line side and the power line side is electrically connected to the circuit structure; and a heat dissipation structure formed on the circuit structure of the packaging module.

In the aforementioned electronic package, the heat dissipation structure includes a patterned dielectric layer and a metal layer embedded in the patterned dielectric layer and exposed from opposite sides of the patterned dielectric layer.

In the aforementioned electronic package, the metal layer is in a form of a ring array or a tic-tac-toe array.

In the aforementioned electronic package, the heat dissipation structure is a metal layer.

The aforementioned electronic package further comprises a seed layer formed between the heat dissipation structure and the circuit structure.

The aforementioned electronic package further comprises a metal bonding layer formed on the heat dissipation structure.

The aforementioned electronic package further comprises a heat dissipation material formed on the metal bonding layer.

The aforementioned electronic package further comprises a heat dissipation member connected to the heat dissipation material and disposed on the carrier structure to cover the packaging module.

In the aforementioned electronic package, the metal bonding layer comprises a titanium layer, a nickel/vanadium layer, and a gold layer.

In the aforementioned electronic package, the packaging module further comprises a plurality of conductive pillars embedded in the encapsulating layer and electrically connected to the circuit structure and the wiring structure.

The present disclosure also provides a method of manufacturing an electronic package, the method comprises: providing a packaging module including an encapsulating layer, an electronic component, a circuit structure, and a wiring structures, wherein the encapsulating layer has a first surface and a second surface opposing the first surface, the electronic component is embedded in the encapsulating layer, and the circuit structure is formed on the second surface of the encapsulating layer and electrically connected to the electronic component, the wiring structure is formed on the first surface of the encapsulating layer and electrically connected to the electronic component, and the electronic component is a backside power delivery chip having a power line side and a signal line side opposing the power line side, one of the power line side and the signal line side is electrically connected to the wiring structure, and another one of the signal line side and the power line side is electrically connected to the circuit structure; forming a heat dissipation structure on the circuit structure; and disposing the package module on one side of a carrier structure.

In the aforementioned manufacturing method, the heat dissipation structure includes a patterned dielectric layer and a metal layer embedded in the patterned dielectric layer and exposed from opposite sides of the patterned dielectric layer.

The aforementioned manufacturing method, further comprises forming a seed layer on the circuit structure first, and then forming the heat dissipation structure on the seed layer.

In the aforementioned manufacturing method, the patterned dielectric layer is formed on the seed layer first through an exposure and development process, and then the metal layer is formed in the patterned dielectric layer.

In the aforementioned manufacturing method, the metal layer is in a form of a ring array or a tic-tac-toe array.

In the aforementioned manufacturing method, the heat dissipation structure is made of copper.

The aforementioned manufacturing method, further comprises forming a metal bonding layer on the heat dissipation structure.

The aforementioned manufacturing method, further comprises forming a heat dissipation material on the metal bonding layer.

The aforementioned manufacturing method, further comprises after the packaging module is disposed on the carrier structure, disposing a heat dissipation member on the carrier structure and connecting the heat dissipation member to the heat dissipation material to cover the packaging module.

In the aforementioned manufacturing method, the metal bonding layer comprises a titanium layer, a nickel/vanadium layer, and a gold layer.

In the aforementioned manufacturing method, the packaging module further comprises a plurality of conductive pillars embedded in the encapsulating layer and electrically connected to the circuit structure and the wiring structure.

As can be understood from the above, the electronic package and manufacturing method thereof according to the present disclosure, the heat dissipation structure can allow the electronic component to dissipate heat through the wiring structure and conductive bumps on the power line side and through the heat dissipation material and heat dissipation member on the signal line side simultaneously, thereby avoiding heat accumulation which causes the risk of excessive temperature and having the advantages of low cost, simple manufacturing process, good implementation convenience, and no need to purchase expensive machines.

### BRIEF DESCRIPTION OF THE DRAWINGS

FIG. 1 is a schematic cross-sectional view of a conventional semiconductor package.

FIG. 2A to FIG. 2E are schematic cross-sectional views of a manufacturing method of an electronic package according to the present disclosure.

FIG. 2B′ is a schematic cross-sectional view of another embodiment of a heat dissipation structure in the electronic package according to the present disclosure.

FIG. 3A and FIG. 3B are top views of heat dissipation structures in different embodiments of the electronic package according to the present disclosure.

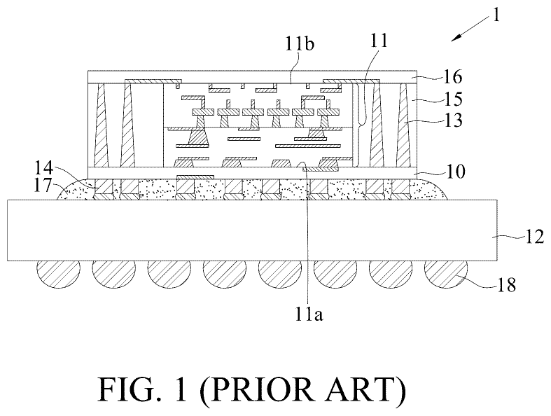

### DETAILED DESCRIPTION

Embodiments of the present disclosure are described below by examples. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

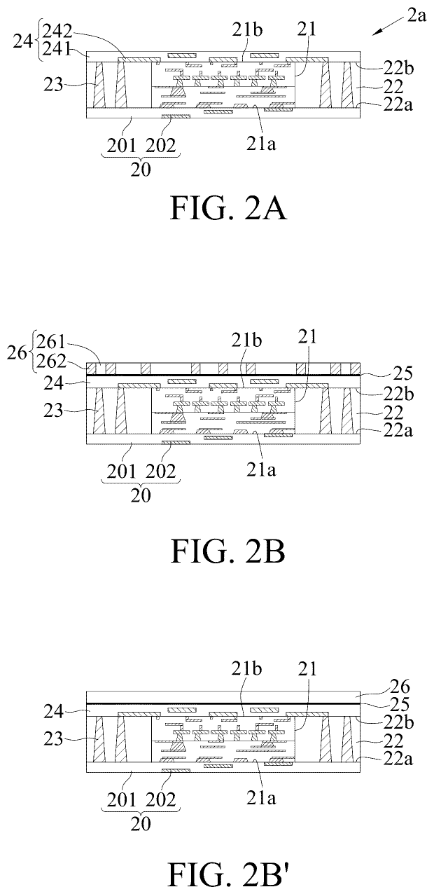

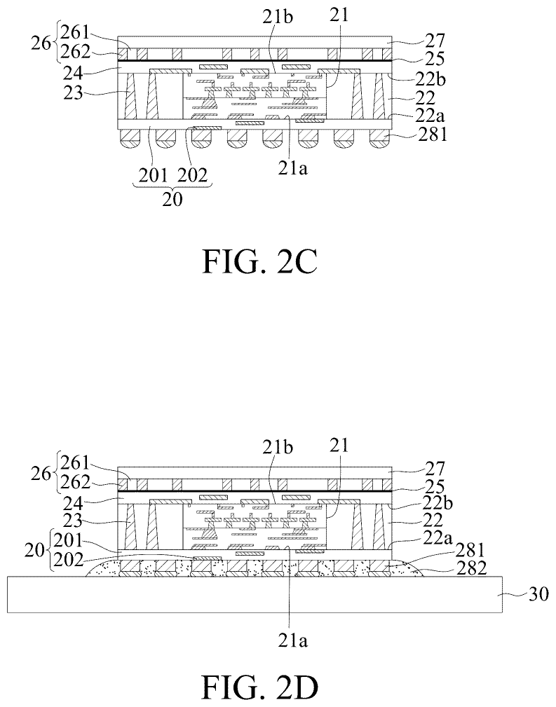

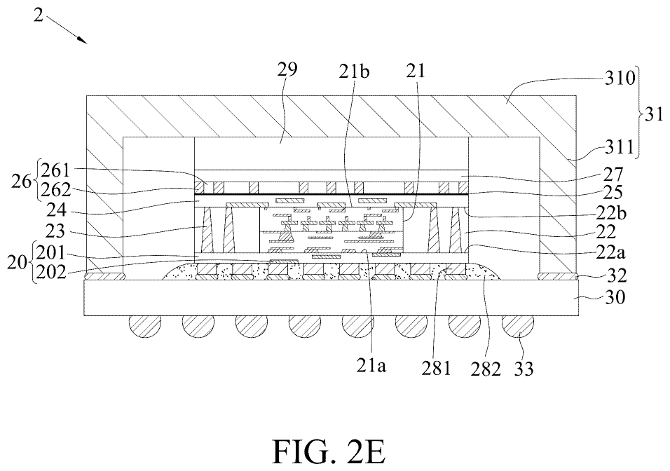

FIG. 2A to FIG. 2E are schematic cross-sectional views of a manufacturing method of an electronic package 2 of the present disclosure.

As shown in FIG. 2A, a packaging module 2a is provided. The packaging module 2a includes a wiring structure 20, an electronic component 21, an encapsulating layer 22, a plurality of conductive pillars 23, and a circuit structure 24.

The wiring structure 20 includes at least one dielectric layer 201 and a circuit layer 202 bonded to the dielectric layer 201. For example, a material forming the dielectric layer 201 may be polybenzoxazole (PBO) or polyimide (PI), prepreg (PP) or other dielectric materials, and the dielectric layer 201 and the circuit layer 202 may be formed using a redistribution layer (RDL) process.

In an embodiment, the electronic component 21 is a backside power delivery chip having a power line side 21a and a signal line side 21b opposing the power line side 21a. The electronic component 21 is connected to the wiring structure 20 with the power line side 21a and electrically connected to the circuit layer 202 with a plurality of electrical contact pads on the power line side 21a.

A plurality of conductive pillars 23 are erected on the wiring structure 20 and electrically connected to the circuit layer 202. In an embodiment, the material forming the plurality of conductive pillars 23 may be, for example, copper metal material or solder material.

The encapsulating layer 22 is formed on the wiring structure 20 and covers the plurality of conductive pillars 23 and the electronic component 21. The encapsulating layer 22 has a first surface 22a and a second surface 22b opposing the first surface 22a. The encapsulating layer 22 is bonded to the wiring structure 20 via the first surface 22a thereof, and opposite end surfaces of the plurality of conductive pillars 23 are exposed from the first surface 22a and the second surface 22b, respectively. The power line side 21a of the electronic component 21 is exposed from the first surface 22a, and the signal line side 21b is exposed from the second surface 22b.

In an embodiment, the encapsulating layer 22 may be an insulating material, such as polyimide (PI), dry film, epoxy resin, or molding compound. For example, the encapsulating layer 22 may be formed on the wiring structure 20 by liquid compound, injection, lamination or compression molding.

The circuit structure 24 is disposed on the signal line side 21b of the electronic component 21 and the second surface 22b of the encapsulating layer 22, and includes at least one dielectric layer 241 and a circuit layer 242 bonded to the dielectric layer 241. For example, a material of the dielectric layer 241 may be polybenzoxazole (PBO), polyimide (PI), prepreg (PP) or other dielectric materials, and the dielectric layer 241 and the circuit layer 242 may be formed by using a redistribution layer (RDL) process such that the circuit layer 242 is electrically connected to the plurality of conductive pillars 23 and the plurality of electrical contact pads on the signal line side 21b of the electronic component 21.

In other embodiments, the electronic component 21 may also be connected to the wiring structure 20 by the signal line side 21b, and connected to the circuit structure 24 by the power line side 21a.

As shown in FIG. 2B, a heat dissipation structure 26 is formed on the circuit structure 24.

In one embodiment, a seed layer 25 may be formed on the circuit structure 24 first, and then the heat dissipation structure 26 may be formed on the seed layer 25. The seed layer 25 is formed of a metal material such as Ti, Cu, Ni, V, Al, W, Au or a combination thereof by sputtering. In an embodiment, the seed layer 25 may be a metal material composed of Ti—Cu, but the present disclosure is not limited to as such.

The heat dissipation structure 26 includes a patterned dielectric layer 261 and a metal layer 262. A patterned dielectric layer 261 is first formed on the circuit structure 24 through an exposure and development process, and then a metal layer 262 is formed in the patterned dielectric layer 261 through an electroplating process, such that the metal layer 262 is embedded in the patterned dielectric layer 261 and exposed from the opposite sides of the patterned dielectric layer 261.

In an embodiment, the patterned dielectric layer 261 may be, for example, an insulating material of polyimide (PI), and the metal layer 262 may be, for example, copper, but the present disclosure is not limited to as such.

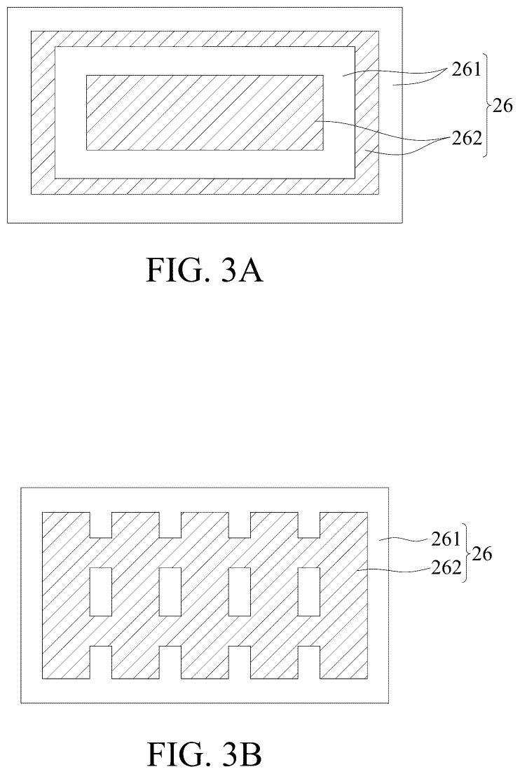

Furthermore, as shown in FIG. 3A, a layout of the metal layer 262 may be in a form of a ring array, or as shown in FIG. 3B, the layout of the metal layer 262 may also be in a form of a tic-tac-toe array, but the present disclosure is not limited to as such. The layout of the metal layer 262 may be changed according to heat dissipation requirements.

In one embodiment, as shown in FIG. 2B′, a metal layer (such as a thick copper layer) may also be formed through an electroplating process as the heat dissipation structure 26 without forming the patterned dielectric layer 261 as mentioned above.

As shown in FIG. 2C, a metal bonding layer 27 is formed on the heat dissipation structure 26 by a sputtering process, and a plurality of conductive bumps 281, such as solder material, are formed on the wiring structure 20.

In an embodiment, the metal bonding layer 27 includes, from bottom to top, a titanium (Ti) layer, a nickel (Ni)/(vanadium (V)) layer, and a gold (Au) layer in sequence from bottom to top. The Ti layer is used to bond the metal layer 262 and Ni(V) layer, and serves as an indium (In) diffusion barrier layer. The Ni(V) layer is used to form an intermetallic compound welding layer with In, and the Au layer is used to prevent oxidation of the Ni(V) layer.

As shown in FIG. 2D, the packaging module 2a is disposed on one side of a carrier structure 30 by a plurality of conductive bumps 281 through a reflow process, and an underfill 282 is filled into a space between the packaging module 2a and the carrier structure 30 to cover a plurality of conductive bumps 281.

The carrier structure 30 is in a form of a packaging carrier, such as a packaging substrate with a core layer and circuit structure, a packaging substrate with a coreless circuit structure, or a through silicon interposer (TSI) with a through-silicon via (TSV) or other type of boards, which includes at least one wiring layer, such as at least one fan-out type redistribution layer (RDL). It should be understood that the carrier structure 30 may also be other board material that carry chips, such as lead frame, wafer, or other board body with metal routing, but the present disclosure is not limited to as such.

As shown in FIG. 2E, a heat dissipation material 29 is formed on the metal bonding layer 27, and a heat dissipation member 31 is disposed on the one side of the carrier structure 30 and connected to the heat dissipation material 29 to cover the packaging module 2a. Then, a heating operation is performed to thermally cure the heat dissipation material 29, and a plurality of conductive components 33 such as solder balls are arranged on the other side of the carrier structure 30 to obtain the electronic package 2. The electronic package 2 may be disposed on an electronic device (not shown) such as a circuit board by the conductive components 33.

In an embodiment, the heat dissipation material 29 is a thermal interface material (TIM), which may be, for example, indium, nano-sintering, or silicon-based resin heat dissipation glue (the filler may be ZnO, Al, Ag, SiO₂, Al₂O₃, etc.), epoxy resin heat dissipation glue (filler may be ZnO, Al, Ag, SiO₂, Al₂O₃, etc.). It should be understood that there are many types of TIMs, but the present disclosure is not limited to as such.

The heat dissipation member 31 includes a sheet-shaped heat dissipation body 310 and a plurality of supporting legs 311 erected on the heat dissipation body 310 so that the heat dissipation body 310 is in contact with and bonded to the heat dissipation member 29, and the supporting legs 311 are bonded to the one side of the carrier structure 30 by an adhesive layer 32. In an embodiment, the heat dissipation member 31 is bonded to the carrier structure 30 in a manner of thermal compression bonding.

The present disclosure further provides an electronic package 2, which includes a carrier structure 30, a packaging module 2a and a heat dissipation structure 26.

The carrier structure 30 is in a form of a packaging carrier, such as a packaging substrate with a core layer and circuit structure, a packaging substrate with a coreless circuit structure, or a through silicon interposer (TSI) with a through-silicon via (TSV) or other type of boards, which includes at least one wiring layer, such as at least one fan-out type redistribution layer (RDL). It should be understood that the carrier structure 30 may also be other board material that carries chips, such as lead frame, wafer, or other board body with metal routing, but the present disclosure is not limited to as such.

The packaging module 2a is disposing on one side of the carrier structure 30 and includes a wiring structure 20, an electronic component 21, an encapsulating layer 22, a plurality of conductive pillars 23 and a circuit structure 24.

The wiring structure 20 is disposed on the one side of the carrier structure 30 through a plurality of conductive bumps 281 such as solder material and an underfill 282 covering the conductive bumps 281, and includes at least one dielectric layer 201 and a circuit layer 202 bonded to the dielectric layer 201.

The electronic component 21 is a backside power delivery chip having a power line side 21a and a signal line side 21b opposing the power line side 21a. The electronic component 21 is connected to the wiring structure 20 with the power line side 21a and electrically connected to the circuit layer 202 with a plurality of electrical contact pads on the power line side 21a.

A plurality of conductive pillars 23 are disposed on the wiring structure 20 and electrically connected to the circuit layer 202.

The encapsulating layer 22 is formed on the wiring structure 20 and covers the plurality of conductive pillars 23 and the electronic component 21. The encapsulating layer 22 has a first surface 22a and a second surface 22b opposing the first surface 22a. The encapsulating layer 22 is bonded to the wiring structure 20 via the first surface 22a thereof, and opposite end surfaces of the plurality of conductive pillars 23 are exposed from the first surface 22a and the second surface 22b, respectively. The power line side 21a of the electronic component 21 is exposed from the first surface 22a, and the signal line side 21b is exposed from the second surface 22b.

The circuit structure 24 is disposed on the signal line side 21b of the electronic component 21 and the second surface 22b of the encapsulating layer 22, and includes at least one dielectric layer 241 and a circuit layer 242 bonded to the dielectric layer 241, such that the circuit layer 242 is electrically connected to the plurality of conductive pillars 23 and the plurality of electrical contact pads on the signal line side 21b of the electronic component 21.

The heat dissipation structure 26 is disposed on the circuit structure 24 and includes a patterned dielectric layer 261 and a metal layer 262 embedded in the patterned dielectric layer 261 and exposed from opposite sides of the patterned dielectric layer 261.

In an embodiment, the patterned dielectric layer 261 may be, for example, an insulating material of polyimide (PI), and the metal layer 262 may be, for example, copper, but the present disclosure is not limited to as such.

In one embodiment, a layout of the metal layer 262 may be in a form of a ring array or a tic-tac-toe array, but the present disclosure is not limited to as such.

In one embodiment, the heat dissipation structure 26 may also be a thick copper layer without including the aforementioned patterned dielectric layer 261.

In one embodiment, a seed layer 25 may be formed between the circuit structure 24 and the heat dissipation structure 26, such as a metal material composed of Ti/Cu, but the present disclosure is not limited to as such.

The electronic package 2 further includes a metal bonding layer 27 formed on the heat dissipation structure 26. In an embodiment, the metal bonding layer 27 includes, from bottom to top, a titanium (Ti) layer, a nickel (Ni)/(vanadium (V)) layer, and a gold (Au) layer. The Ti layer is used to bond the metal layer 262 and Ni(V) layer, and serves as an indium (In) diffusion barrier layer. The Ni(V) layer is used to form an intermetallic compound welding layer with In, and the Au layer is used to prevent oxidation of the Ni(V) layer.

The electronic package 2 further includes a heat dissipation material 29 formed on the metal bonding layer 27. In an embodiment, the heat dissipation material 29 is a thermal interface material (TIM).

The electronic package 2 further includes a heat dissipation member 31 disposed on the one side of the carrier structure 30 and connected to the heat dissipation material 29. The heat dissipation member 31 includes a sheet-shaped heat dissipation body 310 and a plurality of supporting legs 311 erected on the heat dissipation body 310 so that the heat dissipation body 310 is in contact with and bonded to the heat dissipation member 29, and the supporting legs 311 are bonded to the one side of the carrier structure 30 via an adhesive layer 32.

In the electronic package 2, a plurality of conductive components 33 such as solder balls may be arranged on the other side of the carrier structure 30 for connecting to an electronic device (not shown) such as a circuit board.

In view of the above, the electronic package and manufacturing method thereof according to the present disclosure, the heat dissipation structure can allow the electronic component to dissipate heat through the wiring structure and conductive bumps on the power line side and through the heat dissipation material and heat dissipation member on the signal line side simultaneously, thereby avoiding heat accumulation which causes the risk of excessive temperature and having the advantages of low cost, simple manufacturing process, good implementation convenience, and no need to purchase expensive machines.

Furthermore, the heat dissipation structure of the electronic package of the present disclosure is a composite layer of a patterned dielectric layer (such as PI) and a metal layer (such as Cu). In the subsequent thermal cycle or thermal process, in addition to avoiding delamination concerns caused by large volume change mismatches, it can also alleviate stress problems between the heat dissipation structure and other layers (such as circuit structures or metal bonding layers).

In addition, since the heat dissipation structure is in the electronic package of the present disclosure, the metal bonding layer is not directly bonded to the dielectric layer of the circuit structure, thereby avoiding bonding problems such as delamination due to film stress.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure;
a packaging module disposed on one side of the carrier structure and including an encapsulating layer, an electronic component, a circuit structure, and a wiring structure, wherein the encapsulating layer has a first surface and a second surface opposing the first surface, the electronic component is embedded in the encapsulating layer, the circuit structure is formed on the second surface of the encapsulating layer and electrically connected to the electronic component, and the wiring structure is formed on the first surface of the encapsulating layer and electrically connected to the electronic component, and the electronic component is a backside power delivery chip having a power line side and a signal line side opposing the power line side, one of the power line side and the signal line side is electrically connected to the wiring structure, and another one of the signal line side and the power line side is electrically connected to the circuit structure; and
a heat dissipation structure formed on the circuit structure of the packaging module.

2. The electronic package of claim 1, wherein the heat dissipation structure includes a patterned dielectric layer and a metal layer embedded in the patterned dielectric layer and exposed from opposite sides of the patterned dielectric layer.

3. The electronic package of claim 2, wherein the metal layer is in a form of a ring array or a tic-tac-toe array.

4. The electronic package of claim 1, wherein the heat dissipation structure is a metal layer.

5. The electronic package of claim 1, further comprising a seed layer formed between the heat dissipation structure and the circuit structure.

6. The electronic package of claim 1, further comprising a metal bonding layer formed on the heat dissipation structure.

7. The electronic package of claim 6, further comprising a heat dissipation material formed on the metal bonding layer.

8. The electronic package of claim 7, further comprising a heat dissipation member connected to the heat dissipation material and disposed on the carrier structure to cover the packaging module.

9. The electronic package of claim 6, wherein the metal bonding layer comprises a titanium layer, a nickel/vanadium layer, and a gold layer.

10. The electronic package of claim 1, wherein the packaging module further comprises a plurality of conductive pillars embedded in the encapsulating layer and electrically connected to the circuit structure and the wiring structure.

11. A method of manufacturing an electronic package, comprising:
providing a packaging module including an encapsulating layer, an electronic component, a circuit structure, and a wiring structures, wherein the encapsulating layer has a first surface and a second surface opposing the first surface, the electronic component is embedded in the encapsulating layer, the circuit structure is formed on the second surface of the encapsulating layer and electrically connected to the electronic component, the wiring structure is formed on the first surface of the encapsulating layer and electrically connected to the electronic component, and the electronic component is a backside power delivery chip having a power line side and a signal line side opposing the power line side, one of the power line side and the signal line side is electrically connected to the wiring structure, and another one of the signal line side and the power line side is electrically connected to the circuit structure;
forming a heat dissipation structure on the circuit structure; and
disposing the package module on a side of a carrier structure.

12. The method of claim 11, wherein the heat dissipation structure includes a patterned dielectric layer and a metal layer embedded in the patterned dielectric layer and exposed from opposite sides of the patterned dielectric layer.

13. The method of claim 12, further comprising forming a seed layer on the circuit structure first, and then forming the heat dissipation structure on the seed layer.

14. The method of claim 13, wherein the patterned dielectric layer is formed on the seed layer first through an exposure and development process, and then the metal layer is formed in the patterned dielectric layer.

15. The method of claim 12, wherein the metal layer is in a form of a ring array or a tic-tac-toe array.

16. The method of claim 11, wherein the heat dissipation structure is made of copper.

17. The method of claim 11, further comprising forming a metal bonding layer on the heat dissipation structure.

18. The method of claim 17, further comprising forming a heat dissipation material on the metal bonding layer.

19. The method of claim 18, further comprising after the packaging module is disposed on the carrier structure, disposing a heat dissipation member on the carrier structure and connecting the heat dissipation member to the heat dissipation material to cover the packaging module.

20. The method of claim 17, wherein the metal bonding layer comprises a titanium layer, a nickel/vanadium layer, and a gold layer.

21. The method of claim 11, wherein the packaging module further comprises a plurality of conductive pillars embedded in the encapsulating layer and electrically connected to the circuit structure and the wiring structure.
